(19) United States
(12) Patent Application Publication
(10) Pub. No.: US 2026/0204215 A1
(43) Pub. Date: Jul. 16, 2026

(54) DISPLAY APPARATUS AND ELECTRONIC DEVICE INCLUDING THE SAME

(71) Applicant: Samsung Display Co., Ltd., Yongin-Si (KR)

(72) Inventors: Daewoong Ham, Yongin-si (KR); Taehoon Kwon, Yongin-si (KR); Myeongeon Kim, Yongin-si (KR); Mina Kim, Yongin-si (KR); Sungjin Yum, Yongin-si (KR)

(21) Appl. No.: 19/331,149

(22) Filed: Sep. 17, 2025

(30) Foreign Application Priority Data
Jan. 16, 2025 (KR) 10-2025-0006867

(51) Int. Cl. G09G 3/3233

(52) U.S. Cl. CPC G09G 3/3233; G09G 2300/0413; G09G 2300/0426; G09G 2300/0819; G09G 2300/0842; G09G 2310/08

(57) ABSTRACT

A display apparatus includes a substrate, a pixel, a first power voltage line, a second power voltage line, and a first dummy circuit. The substrate includes a display area and a non-display area outside the display area. The pixel is disposed in the display area and includes a pixel circuit and a light-emitting diode electrically connected to the pixel circuit. The first power voltage line is disposed in the non-display area and configured to transmit a first power voltage. The second power voltage line is disposed in the non-display area and is configured to transmit a second power voltage. The first dummy circuit is disposed in the non-display area and is configured to operate as a sink-current path electrically connecting the first power voltage line to the second power voltage line.

### CROSS-REFERENCE TO RELATED APPLICATION

This application is based on and claims priority under 35 U.S.C. § 119 to Korean Patent Application No. 10-2025-0006867, filed on Jan. 16, 2025, in the Korean Intellectual Property Office, the disclosure of which is incorporated by reference herein in its entirety.

### BACKGROUND

### 1. Field

One or more embodiments relate to a display apparatus and an electronic device including the display apparatus.

### 2. Description of the Related Art

A display apparatus may include a plurality of pixels. Each of the plurality of pixels may include a display element that emits light of a certain color and a pixel circuit configured to control the brightness of the display element. The pixel circuit may include transistors, capacitors, and lines.

Recently, display apparatuses have been reduced in thickness and weight, and thus may be applied to various electronic devices. Accordingly, various types of display apparatuses and electronic devices including the display apparatuses have been designed.

### SUMMARY

Embodiments may provide a display apparatus that display high-quality images and an electronic device including the display apparatus.

Additional aspects will be set forth in part in the description which follows and, in part, will be apparent from the description, or may be learned by practice of the presented embodiments of the disclosure.

According to one or more embodiments, a display apparatus includes a substrate including a display area and a non-display area outside the display area, a pixel disposed in the display area and including a pixel circuit and a light-emitting diode electrically connected to the pixel circuit, a first power voltage line disposed in the non-display area and configured to transmit a first power voltage, a second power voltage line disposed in the non-display area and configured to transmit a second power voltage, and a first dummy circuit disposed in the non-display area and configured to operate as a sink-current path electrically connecting the first power voltage line to the second power voltage line.

In an embodiment, the pixel circuit may include a first transistor including a first terminal electrically connected to a first node, a gate electrically connected to a second node, and a second terminal electrically connected to a third node, a second transistor electrically connected between a data line and the first node, a third transistor electrically connected between the first power voltage line and the first node, a fourth transistor electrically connected between the third node and a fourth node, and a fifth transistor electrically connected between a bias voltage line and the first node, and the light-emitting diode may be electrically connected to the fourth node.

In an embodiment, the pixel circuit may further include a sixth transistor electrically connected between the second node and the third node, a seventh transistor electrically connected between a first initialization voltage line and the second node, and an eighth transistor electrically connected between a second initialization voltage line and the fourth node.

In an embodiment, the first dummy circuit may include a first transistor including a first terminal electrically connected to a first node, a gate electrically connected to a second node, and a second terminal electrically connected to a third node, a second transistor electrically connected between a data line and the first node, a third transistor electrically connected between the first power voltage line and the first node, a fourth transistor electrically connected between the third node and a fourth node, a fifth transistor electrically connected between a bias voltage line and the first node, and a sixth transistor electrically connected between the fourth node and an auxiliary electrode or auxiliary voltage line configured to transmit the second power voltage.

In an embodiment, the first dummy circuit may further include a seventh transistor electrically connected between the second node and the third node, an eighth transistor electrically connected between a first initialization voltage line and the second node, and a ninth transistor electrically connected between a second initialization voltage line and the fourth node.

In an embodiment, a gate of each of the third transistor, the fourth transistor, and the sixth transistor may be electrically connected to an emission control line.

In an embodiment, a frame may include a first scan period in which a data signal is supplied to the data line and the pixel emits light with a brightness corresponding to the data signal, and a second scan period in which the data signal supplied in the first scan period is maintained and the pixel emits light with the brightness corresponding to the data signal, and a gate-on voltage is supplied to a gate of the fifth transistor during each of the first scan period and the second scan period.

In an embodiment, the second scan period may include a non-emission period and an emission period, and, during the emission period, the third transistor, the fourth transistor, and the sixth transistor may operate as the sink-current path.

In an embodiment, the bias voltage line may be configured to transmit a bias voltage to the first node, and a level of the bias voltage may be higher than a level of the first power voltage.

In an embodiment, the display apparatus may further include a second dummy circuit disposed in the non-display area, and the light-emitting diode may include a pixel electrode electrically connected to the pixel circuit, an opposite electrode, and an emission layer between the pixel electrode and the opposite electrode, and the second dummy circuit may be electrically insulated from the opposite electrode.

According to one or more embodiments, a display apparatus includes a substrate including a display area and a non-display area outside the display area, a pixel disposed in the display area and including a pixel circuit and a light-emitting diode electrically connected to the pixel circuit, a first power voltage line disposed in the non-display area and configured to transmit a first power voltage, a first voltage line disposed in the non-display area and configured to transmit a first voltage lower than the first power voltage, a controller disposed in the non-display area and configured to output a sink-control signal, and a sink-transistor disposed in the non-display area and configured to operate as a sink-current path electrically connecting the first power voltage line to the first voltage line based on the sink-control signal.

In an embodiment, the sink-transistor may include a first terminal electrically connected to the first power voltage line, a second terminal electrically connected to the first voltage line, and a gate electrically connected to the controller.

In an embodiment, the light-emitting diode may include a pixel electrode electrically connected to the pixel circuit, an opposite electrode, and an emission layer between the pixel electrode and the opposite electrode, and the first voltage line may be electrically connected to the opposite electrode.

In an embodiment, the pixel circuit may include a first transistor including a first terminal electrically connected to a first node, a gate electrically connected to a second node, and a second terminal electrically connected to a third node, a second transistor electrically connected between a data line and the first node, a third transistor electrically connected between the first power voltage line and the first node, a fourth transistor electrically connected between the third node and a fourth node, and a fifth transistor electrically connected between a bias voltage line and the first node, and the light-emitting diode may be electrically connected to the fourth node.

In an embodiment, the pixel circuit may further include a sixth transistor electrically connected between the second node and the third node, a seventh transistor electrically connected between a first initialization voltage line and the second node, and an eighth transistor electrically connected between a second initialization voltage line and the fourth node.

In an embodiment, the first voltage line may be electrically connected to the first initialization voltage line or the second initialization voltage line.

In an embodiment, the sink-transistor may be disposed to be adjacent to the controller.

In an embodiment, the substrate may include a first area overlapping the display area, a second area outside the first area, and a bending area between the first area and the second area, and the sink-transistor may be disposed in the second area.

According to one or more embodiments, an electronic device includes a display apparatus, a memory configured to store an application, and one or more processors configured to execute the application and transmit an image data signal and an input control signal to the display apparatus, wherein the display apparatus includes a substrate including a display area and a non-display area outside the display area, a pixel disposed in the display area and including a pixel circuit and a light-emitting diode electrically connected to the pixel circuit, a first power voltage line disposed in the non-display area and configured to transmit a first power voltage, a second power voltage line disposed in the non-display area and configured to transmit a second power voltage, and a first dummy circuit disposed in the non-display area and configured to operate as a sink-current path electrically connecting the first power voltage line to the second power voltage line.

According to one or more embodiments, an electronic device includes a display apparatus, a memory configured to store an application, and one or more processors configured to execute the application and transmit an image data signal and an input control signal to the display apparatus, wherein the display apparatus includes a substrate including a display area and a non-display area outside the display area, a pixel disposed in the display area and including a pixel circuit and a light-emitting diode electrically connected to the pixel circuit, a first power voltage line disposed in the non-display area and configured to transmit a first power voltage, a first voltage line disposed in the non-display area and configured to transmit a first voltage lower than the first power voltage, a controller disposed in the non-display area and configured to output a sink-control signal, and a sink-transistor disposed in the non-display area and configured to operate as a sink-current path electrically connecting the first power voltage line to the first voltage line based on the sink-control signal.

Other aspects, features, and advantages other than those described above will now become apparent from the following drawings, claims, and the detailed description of the disclosure.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic diagram of a display apparatus according to an embodiment;

FIG. 2 is a schematic perspective view of a display apparatus according to an embodiment;

FIG. 3 is a schematic plan view of a display apparatus according to an embodiment;

FIG. 4 is a schematic cross-sectional diagram of a display apparatus according to an embodiment;

FIG. 5 is a schematic equivalent circuit diagram of a pixel according to an embodiment;

FIG. 6 is a schematic equivalent circuit diagram of a first dummy pixel according to an embodiment;

FIG. 7 is a schematic equivalent circuit diagram of a second dummy pixel according to an embodiment;

FIGS. 8 and 9 are conceptual diagrams for describing a method of driving a display apparatus according to a driving frequency;

FIG. 10 is a schematic timing diagram of signals supplied during a first scan period and a second scan period;

FIG. 11 is a schematic timing diagram of signals supplied during a non-emission period of the first scan period;

FIG. 12 is a schematic timing diagram of signals supplied during a non-emission period of the second scan period;

FIG. 13 is a schematic plan view of a display apparatus according to an embodiment;

FIG. 14 is a schematic equivalent circuit diagram of a sink circuit according to an embodiment;

FIG. 15 is a block diagram of an electronic device according to an embodiment; and

FIGS. 16, 17, and 18 are schematic diagrams of electronic devices according to various embodiments.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the word “or” means logical “or” so that, unless the context indicates otherwise, the expression “A, B, or C” means “A and B and C,” “A and B but not C,” “A and C but not B,” “B and C but not A,” “A but not B and not C,” “B but not A and not C,” and “C but not A and not B.” Throughout the disclosure, the expression “at least one of a, b and c” indicates only a, only b, only c, both a and b, both a and c, both b and c, all of a, b, and c, or variations thereof.

As the disclosure allows for various changes and numerous embodiments, particular embodiments will be illustrated in the drawings and described in detail in the written description. Effects and features of the disclosure and methods of achieving the same will be apparent with reference to embodiments and drawings described below in detail. The disclosure may, however, be embodied in many different forms and should not be construed as being limited to the embodiments set forth herein.

The disclosure will now be described more fully with reference to the accompanying drawings, in which embodiments of the disclosure are shown. Like reference numerals in the drawings denote like elements, and thus their description will not be repeated.

In the disclosure, while such terms as “first,” “second,” etc., may be used to describe various elements, such elements must not be limited to the above terms.

In the disclosure, an expression used in the singular encompasses the expression of the plural, unless it has a clearly different meaning in the context.

In the disclosure, it is to be understood that the terms such as “comprising,” “including,” and “having” are intended to indicate the existence of the features, or elements disclosed in the present disclosure, and are not intended to preclude the possibility that one or more other features or elements may exist or may be added.

In the disclosure, it will be understood that when a layer, region, or component is referred to as being formed on another layer, region, or component, it can be directly or indirectly formed on the other layer, region, or component. That is, for example, intervening layers, regions, or components may be present.

In the disclosure, it will be understood that when a layer, region, or component is referred to as being connected to another layer, region, or component, it can be directly or indirectly connected to the other layer, region, or component. That is, for example, intervening layers, regions, or components may be present. For example, it will be understood that when a layer, region, or component is referred to as being electrically connected to another layer, region, or component, it can be directly or indirectly electrically connected to the other layer, region, or component. That is, for example, intervening layers, regions, or components may be present.

In the specification, the x direction, the y direction, and the z direction are not limited to three axes on the orthogonal coordinates system, and may be interpreted in a broad sense including the same. For example, the x direction, the y direction, and the z direction may be perpendicular to one another, or may represent different directions that are not perpendicular to one another.

In the specification, a “plan view” indicates that a portion of a target object is seen from above (for example, when viewed from a direction perpendicular to an upper surface of a substrate), and a ‘cross-sectional view” indicates that a portion of a target object is vertically cut and the cross-section is viewed from the side.

In the specification, a first component “overlapping” a second component indicates that the first component is positioned above or below the second component so that at least a portion of the first component overlaps the second component in a plan view.

In the specification, “on” used in connection with a device state may refer to an activated state of the device, and “off” may refer to a deactivated state of the device. “On” used in connection with a signal received by a device may refer to a signal that activates the device, and “off” may refer to a signal that deactivates the device. The device may be activated by a high-level voltage or a low-level voltage. For example, a P-channel transistor (P-type transistor) is activated by a low-level voltage, and an N-channel transistor (N-type transistor) is activated by a high-level voltage. Accordingly, it should be understood that “on” voltages for the P-type and N-type transistors are opposite (low versus high) voltage levels.

In the disclosure, when a certain embodiment may be implemented differently, a specific process order may be performed differently from the described order. For example, two consecutively described processes may be performed substantially at the same time or performed in an order opposite to the described order.

Sizes of elements in the drawings may be exaggerated or reduced for convenience of explanation. In other words, since sizes and thicknesses of components in the drawings are arbitrarily illustrated for convenience of explanation, the following embodiments are not limited thereto.

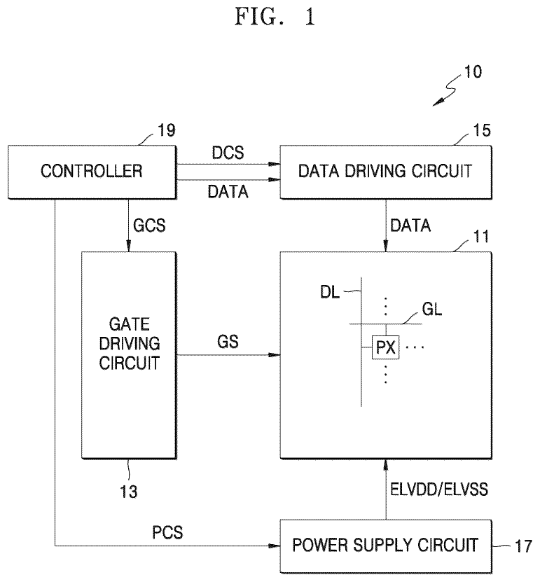

FIG. 1 is a schematic diagram of a display apparatus according to an embodiment.

Referring to FIG. 1, a display apparatus 10 may include a pixel unit 11, a gate driving circuit 13, a data driving circuit 15, a power supply circuit 17, and a controller 19.

The pixel unit 11 may include a plurality of pixels PX electrically connected to data lines DL and gate lines GL. The plurality of pixels PX may be disposed in various forms, such as a stripe arrangement, a PENTILE™ arrangement (diamond arrangement), a mosaic arrangement, or the like, to implement an image. Each pixel PX may include an organic light-emitting diode as a display element (light-emitting element), and the organic light-emitting diode may be connected to a pixel circuit. The pixel circuit may include a plurality of transistors and at least one capacitor. The pixel PX may emit, for example, red, green, blue, or white light through the organic light-emitting diode. Each pixel PX may be connected to at least one corresponding gate line among a plurality of gate lines GL and a corresponding data line among a plurality of data lines DL.

The gate lines GL may each extend in a row direction and be connected to pixels PX positioned in the same row. The gate lines GL may each be configured to transfer a gate signal to the pixels PX in the same row. The data lines DL may each extend in a column direction and be connected to pixels PX positioned in the same column. The data lines DL may each be configured to transfer a data signal to each of the pixels PX in the same column in synchronization with the gate signal.

The gate driving circuit 13 may be connected to the plurality of gate lines GL, generate a gate signal in response to a control signal GCS from the controller 19, and sequentially supply the gate signal to the plurality of gate lines GL. The gate line GL may be connected to a gate of a transistor included in the pixel PX. The gate signal may be a gate control signal controlling turn-on and turn-off of a transistor having a gate connected to the gate line GL. The gate signal may be a signal including a gate-on voltage at which the transistor may be turned on and a gate-off voltage at which the transistor may be turned off.

FIG. 1 illustrates that the pixel PX is connected to one gate line GL, but this is an example. The pixel PX may be connected to two or more gate lines, and the gate driving circuit 13 may supply two or more gate signals having different timings at which gate-on voltages are applied to corresponding gate lines.

The data driving circuit 15 may be connected to the plurality of data lines DL, and may supply a data signal to the data lines DL in response to a control signal DCS from the controller 19. The data signal supplied to the data line DL may be supplied to the pixel PX to which the gate signal is supplied. The data driving circuit 15 may convert image data having a gray-scale from the controller 19 into a data signal DATA in a form of voltage or current.

The power supply circuit 17 may generate voltages necessary for driving the pixel PX in response to a control signal PCS from the controller 19. The power supply circuit 17 may generate and supply a first power voltage ELVDD and a second power voltage ELVSS to the pixels PX. The first power voltage ELVDD may be a high-level voltage provided to a first electrode (pixel electrode or anode) of a display element included in the pixel PX. The second power voltage ELVSS may be a low-level voltage provided to a second electrode (opposite electrode or cathode) of a display element included in the pixel PX.

The controller 19 may generate the control signals GCS, DCS, and PCS based on signals input from the outside and supply the generated control signals to the gate driving circuit 13, the data driving circuit 15, and the power supply circuit 17, respectively. The control signal GCS output to the gate driving circuit 13 may include a plurality of clock signals and a gate start signal. The control signal DCS output to the data driving circuit 15 may include a data start signal and clock signals.

The display apparatus 10 may include a display panel, and the display panel may include a substrate. The pixels PX may be disposed in a display area of the substrate. A portion of the entirety of the gate driving circuit 13 may be directly formed in a peripheral area of the substrate during a process of forming a transistor configuring a pixel circuit in the substrate. The data driving circuit 15, the power supply circuit 17, and the controller 19 may each be formed in a form of a separate integrated circuit chip or may be formed in a single integrated circuit chip to be disposed on a circuit board electrically connected to a pad disposed on one side of the substrate. The circuit board may be a flexible printed circuit board. In another embodiment, the data driving circuit 15, the power supply circuit 17, and the controller 19 may be directly disposed on the substrate by using a method of chip on glass (COG) or chip on plastic (COP).

The display apparatus 10 may support a variable refresh rate. A refresh rate is a frequency at which a data signal is actually written to a driving transistor of the pixel PX, which is referred to as a screen scanning rate or a screen reproduction rate, and may indicate the number of image frames reproduced for one second. In an embodiment, the refresh rate may be an output frequency of the gate driving circuit 13 or the data driving circuit 15. A frequency corresponding to the refresh rate may be a driving frequency. The display apparatus 10 may adjust, according to the driving frequency, the output frequency of the gate driving circuit 13 and the output frequency of the data driving circuit 15 corresponding thereto.

The display apparatus 10 supporting the variable refresh rate may operate by changing the driving frequency within a range of a maximum driving frequency and a minimum driving frequency. For example, when the refresh rate is about 60 Hz, a gate signal for writing a data signal from the gate driving circuit 13 may be supplied to each horizontal line (row) 60 times per second. The display apparatus 10 may display an image while changing the driving frequency according to a refresh rate.

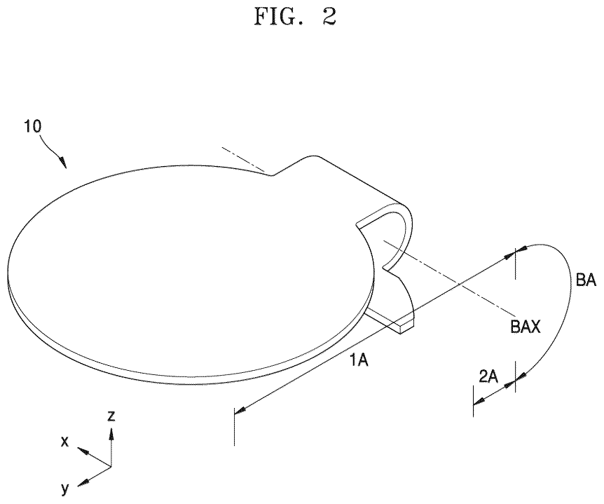

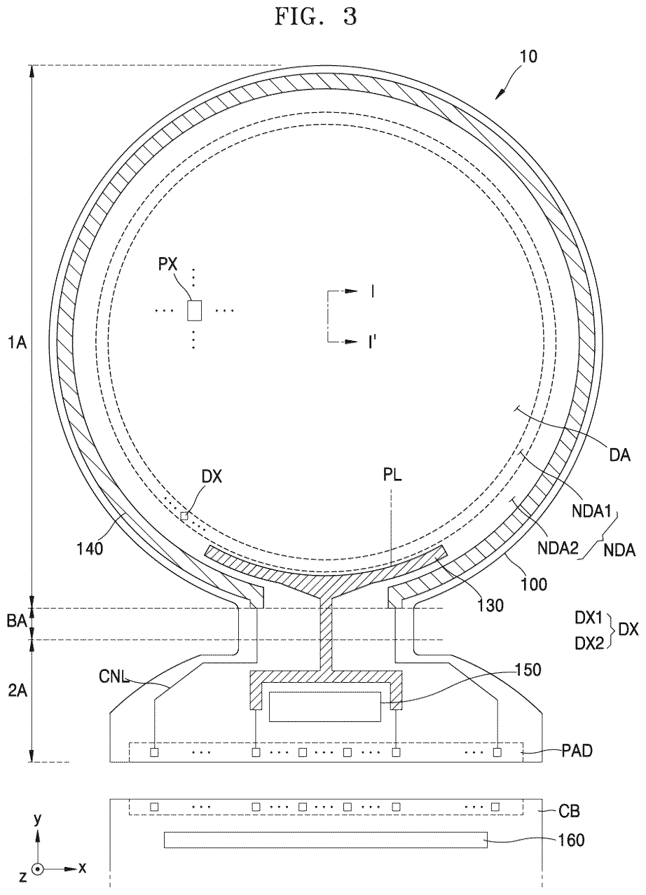

FIG. 2 is a schematic perspective view of a display apparatus according to an embodiment, and FIG. 3 is a schematic plan view of a display apparatus according to an embodiment.

Referring to FIGS. 2 and 3, the display apparatus 10 may include a substrate 100. The substrate 100 may include a first area 1A, a second area 2A, and a bending area BA. Also, the substrate 100 may include a display area DA and a non-display area NDA outside the display area DA. The first area 1A may be a display portion displaying an image by overlapping the display area DA. The second area 2A may be disposed outside the first area 1A and extend to one side of the first area 1A (e.g., a bottom side, in a −y direction). The bending area BA may be disposed between the first area 1A and the second area 2A.

The first area 1A may implement an image through the display area DA. The first area 1A may have a non-rectangular shape. The non-rectangular shape may include, for example, a circular shape, an elliptical shape, a partially circular polygonal shape, or a polygonal shape other than a rectangular shape. In another embodiment, the first area 1A may have a rectangular shape or a rectangular shape with rounded corners.

The substrate 100 has the bending area BA extending in a first direction (e.g., an x direction). The first area 1A and the second area 2A may be spaced apart in a second direction (e.g., a y direction), and the bending area BA may be disposed between the first area 1A and the second area 2A. The substrate 100 may be bent around a bending axis BAX extending in the first direction (e.g., the x direction), as shown in FIG. 2. As shown in FIG. 2, the substrate 100 may be bent with the same radius of curvature with respect to the bending axis BAX, but the disclosure is not limited thereto. The substrate 100 may be bent with non-uniform radii of curvature with respect to the bending axis BAX.

The substrate 100 may include various flexible or bendable materials, for example a polymer resin, such as polyethersulfone, polyacrylate, polyetherimide, polyethylene naphthalate, polyethylene terephthalate, polyphenylene sulfide, polyarylate, polyimide, polycarbonate, or cellulose acetate propionate. The substrate 100 may have a single-layered structure or a multi-layered structure, and may further include an inorganic layer in the case of a multi-layered structure. For example, the substrate 100 may be formed by alternately stacking a base layer including the polymer resin described above and a barrier layer including an inorganic material.

The first area 1A may overlap the display area DA and a portion of the non-display area NDA outside the display area DA. The second area 2A may overlap another portion of the non-display area NDA.

The display area DA may have a shape corresponding to the shape of the first area 1A. For example, as shown in FIG. 2, the first area 1A may be approximately circular in a plan view, and the display area DA may be approximate circular in a plan view in correspondence to the first area 1A.

A plurality of pixels PX, gate lines GL (refer to FIG. 1), data lines DL (refer to FIG. 1), and driving voltage lines PL, which are connected to the pixels PX, may be disposed in the display area DA. Each of the pixels PX may include a pixel circuit and a display element electrically connected to the pixel circuit.

The non-display area NDA may include a first non-display area NDA1 adjacent to the display area DA and a second non-display area NDA2 outside the first non-display area NDA1. Dummy pixels DX may be disposed in the first non-display area NDA1. A dummy pixel DX indicates a sub-pixel that includes a dummy circuit that has a configuration substantially identical or similar to the pixel circuit but does not connected to a display element and thus does not emit light.

In an embodiment, the dummy pixels DX may include first dummy pixels DX1 and at least one second dummy pixel DX2. The first dummy pixels DX1 may include a first dummy circuit. The first dummy circuit may not include a display element and may be electrically insulated from an opposite electrode to which a second power voltage is supplied.

The second dummy pixel DX2 may be configured to operate as a sink-current path electrically connecting a first power voltage line 130 to a second power voltage line 140. At least one dummy pixel DX among the dummy pixels DX may be the second dummy pixel DX2, and the remaining dummy pixels DX may be the first dummy pixels DX1.

The first power voltage line 130 and the second power voltage line 140 may be disposed in the second non-display area NDA2 of the first area 1A. Also, the gate driving circuit 13 (refer to FIG. 1) may be disposed in the second non-display area NDA2.

The first power voltage line 130 may be disposed in the second non-display area NDA2 of the first area 1A to surround a portion of the display area DA. The first power voltage line 130 may be disposed to correspond to a bottom side of the second non-display area NDA2 (e.g., in the −x direction) of the first area 1A. The first power voltage line 130 may be electrically connected to the driving voltage lines PL configured to deliver the first power voltage ELVDD (refer to FIG. 1) to the pixels PX disposed in the display area DA. The first power voltage line 130 may be electrically connected to a second driving integrated circuit 160 through a pad of a pad unit PAD. In an embodiment, the second driving integrated circuit 160 may include the power supply circuit 17 (refer to FIG. 1) supplying the first power voltage ELVDD. The first power voltage line 130 may include a portion extending to the second area 2A to be connected to the pad of the pad unit PAD and may be electrically connected to the pad unit PAD through a connection line.

The second power voltage line 140 may be disposed in the second non-display area NDA2 of the first area 1A to surround at least a portion of the display area DA. The second power voltage line 140 may have a loop shape with a bottom side (e.g., in the −x direction) open in the second non-display area NDA2. The second power voltage line 140 may be electrically connected to an opposite electrode configured to deliver the second power voltage ELVSS (refer to FIG. 1) to the pixels PX disposed in the display area DA. The second power voltage line 140 may be electrically connected to the pad of the pad unit PAD. The second power voltage line 140 may be disposed to overlap the first area 1A and may be electrically connected to the pad unit PAD through a connection line CNL. The second power voltage line 140 may be electrically connected to the second driving integrated circuit 160 through the pad of the pad unit PAD.

The gate driving circuit 13 (refer to FIG. 1) may be disposed in the second non-display area NDA2 of the first area 1A. The gate driving circuit 13 may be disposed on the left side, right side, or both sides of the display area DA.

A first driving integrated circuit 150 may be disposed in the second area 2A of the substrate 100. The first driving integrated circuit 150 may be directly disposed on an upper portion of the substrate 100 in a COG or COP method. The first driving integrated circuit 150 may include the controller 19 (refer to FIG. 1). For example, the first driving integrated circuit 150 may generate control signals based on signals input from the outside and supply the generated control signals to the gate driving circuit 13 (refer to FIG. 1), the data driving circuit 15 (refer to FIG. 1), and the power supply circuit 17 (refer to FIG. 1). The control signals may include a plurality of clock signals, gate start signals, and data start signals. In an embodiment, the first driving integrated circuit 150 may include the data driving circuit 15 (refer to FIG. 1).

The display apparatus 10 may further include a circuit board CB. The circuit board CB may be connected to the pad unit PAD of the substrate 100. The second driving integrated circuit 160 may be disposed in the circuit board CB. The second driving integrated circuit 160 may include the power supply circuit 17 (refer to FIG. 1). The second driving integrated circuit 160 may generate and supply the first power voltage ELVDD to the first power voltage line 130 and may generate and supply the second power voltage ELVSS to the second power voltage line 140.

FIG. 3 illustrates that the first driving integrated circuit 150 is disposed in the substrate 100, and the second driving integrated circuit 160 is disposed in the circuit board CB, but the disclosure is not limited thereto. In another embodiment, the first driving integrated circuit 150 and the second driving integrated circuit 160 may be disposed in the circuit board CB. In another embodiment, the circuit board CB may be omitted, and the first driving integrated circuit 150 and the second driving integrated circuit 160 may be directly disposed on the substrate 100 in a COG or COP method.

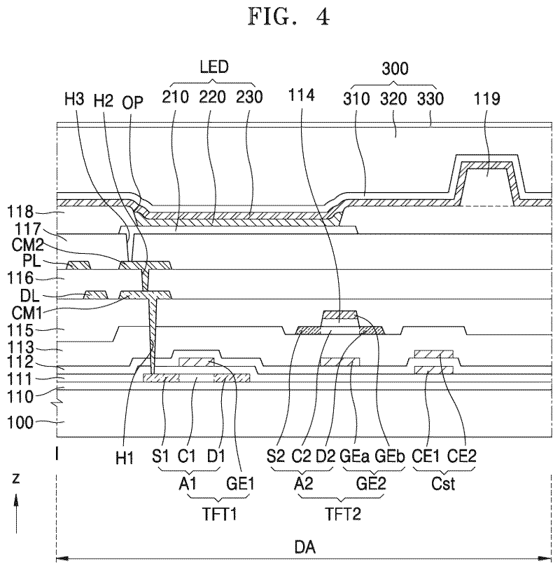

FIG. 4 is a schematic cross-sectional diagram of a display apparatus according to an embodiment. FIG. 4 is a cross-sectional view of the display apparatus taken along a line I-I′ of FIG. 3.

Referring to FIG. 4, the display apparatus 10 may include the substrate 100, a first thin-film transistor TFT1, a second thin-film transistor TFT2, a storage capacitor Cst, and a light-emitting diode LED. The first thin-film transistor TFT1 may include a silicon-based semiconductor material, and the second thin-film transistor TFT2 may include an oxide-based semiconductor material. Also, the display apparatus 10 may include an encapsulation layer 300 sealing the light-emitting diode LED.

The substrate 100 may include a glass material, a ceramic material, a metal material, or a polymer resin. The substrate 100 may include various materials which are flexible or bendable. When the substrate 100 is flexible or bendable, the substrate 100 may include polyethersulfone, polyacrylate, polyetherimide, polyethylene naphthalate, polyethylene terephthalate, polyarylate, polyimide, cellulose acetate propionate, or mixtures thereof. The substrate 100 may have a single-layered structure or multi-layered structure of the materials described above, and may further include an inorganic layer in case of a multi-layered structure.

A buffer layer 110 may be disposed on the substrate 100, and may increase the smoothness of an upper surface of the substrate 100 and prevent or reduce penetration of impurities from the substrate 100 to a silicon semiconductor layer. The buffer layer 110 may have a single-layered structure or a multi-layered structure, each including an inorganic insulating material such as silicon oxide, silicon nitride, and silicon oxynitride.

The first thin-film transistor TFT1 may be disposed on the buffer layer 110. The first thin-film transistor TFT1 may include a first semiconductor layer A1 including a silicon semiconductor material and a gate electrode GE1 disposed on the first semiconductor layer A1. In an embodiment, the first semiconductor layer A1 may include polysilicon. The first semiconductor layer A1 may include a source area S1 and a drain area D1, which are doped with impurities and have conductivities, and a channel area C1 disposed between the source area S1 and the drain area D1. Any one of the source area S1 and the drain area D1 of the first thin-film transistor TFT1 may function as a first terminal of the first thin-film transistor TFT1, and the remaining one thereof may function as a second terminal of the first thin-film transistor TFT1. The positions of the source area S1 and the drain area D1 may be interchanged.

The gate electrode GE1 of the first thin-film transistor TFT1 may be disposed to overlap the channel area C1 of the first semiconductor layer A1 in a plan view, and may include a single-layered structure or a multi-layered structure, each including a conductive material such as molybdenum (Mo), copper (Cu), titanium (Ti), and aluminum (Al).

A first insulating layer 111 may be disposed between the first semiconductor layer A1 and the gate electrode GE1 of the first thin-film transistor TFT1. The first insulating layer 111 may include a single-layered structure or a multi-layered structure, each including an inorganic insulating material such as silicon oxide, silicon nitride, or silicon oxynitride.

A first electrode CE1 of the storage capacitor Cst may be disposed on the same layer as the gate electrode GE1 of the first thin-film transistor TFT1. For example, the first electrode CE1 of the storage capacitor Cst may be disposed on the first insulating layer 111. In the specification, ‘A and B being disposed on the same layer’ indicates that A and B are formed by the same process and have substantially the same materials, physical properties, and layer structures.

A second insulating layer 112 may be disposed on the gate electrode GE1 of the first thin-film transistor TFT1 and the first electrode CE1 of the storage capacitor Cst. The second insulating layer 112 may include a single-layered structure or a multi-layered structure, each including an inorganic insulating material such as silicon oxide, silicon nitride, or silicon oxynitride.

A second electrode CE2 of the storage capacitor Cst may be disposed on the second insulating layer 112. The second electrode CE2 of the storage capacitor Cst may be disposed to overlap the first electrode CE1. The second electrode CE2 of the storage capacitor Cst may include a single-layered structure or a multi-layered structure, each including a conductive material such as Mo, Cu, Ti, and Al.

The second thin-film transistor TFT2 may be disposed on the second insulating layer 112. The second thin-film transistor TFT2 may include a second semiconductor layer A2 including an oxide semiconductor material and a gate electrode GE2 disposed to overlap the second semiconductor layer A2 in a plan view.

A third insulating layer 113 may be disposed on the second electrode CE2 of the storage capacitor Cst. The third insulating layer 113 may include a single-layered structure or a multi-layered structure, each including an inorganic insulating material such as silicon oxide, silicon nitride, or silicon oxynitride.

The second semiconductor layer A2 of the second thin-film transistor TFT2 may be disposed on the third insulating layer 113. The second semiconductor layer A2 may include a source area S2 and a drain area D2, which have conductivities, and a channel area C2 disposed between the source area S2 and the drain area D2. An oxide semiconductor material may include a zinc-oxide-based material, which may include Zn oxide, In—Zn oxide, Ga—In—Zn oxide, or the like. For example, the oxide semiconductor material may include In—Ga—Zn—O (IGZO), In—Sn—Zn—O (ITZO), or In—Ga—Sn—Zn—O (IGTZO).

The gate electrode GE2 of the second thin-film transistor TFT2 may include a lower gate electrode GEa disposed on a lower portion of the second semiconductor layer A2 and an upper gate electrode GEb disposed on an upper portion of the second semiconductor layer A2. The lower gate electrode GEa and the upper gate electrode GEb may be disposed to overlap the channel area C2 of the second semiconductor layer A2 of the second thin-film transistor TFT2 in a plan view. The lower gate electrode GEa may be disposed on the same layer of the second electrode CE2 of the storage capacitor Cst. For example, the lower gate electrode GEa may be disposed on the second insulating layer 112, and the third insulating layer 113 may be disposed between the second semiconductor layer A2 and the lower gate electrode GEa.

A fourth insulating layer 114 may be disposed between the upper gate electrode GEb and the second semiconductor layer A2 of the second thin-film transistor TFT2. The fourth insulating layer 114 may be formed through the same mask process as the upper gate electrode GEb, and in this case, the fourth insulating layer 114 may have a shape corresponding to the shape of the upper gate electrode GEb in a plan view. The fourth insulating layer 114 may include a single-layered structure or a multi-layered structure, each including an inorganic insulating material such as silicon oxide, silicon nitride, or silicon oxynitride. The upper gate electrode GEb of the second thin-film transistor TFT2 may include a single-layered structure or a multi-layered structure, each including a conductive material, such as Mo, Cu, Ti, and Al.

A fifth insulating layer 115 may be disposed on the upper gate electrode GEb of the second thin-film transistor TFT2. The fifth insulating layer 115 may include a single-layered structure or a multi-layered structure, each including an inorganic insulating material such as silicon oxide, silicon nitride, or silicon oxynitride.

The data line DL and a first connection electrode CM1 may be disposed on the fifth insulating layer 115. The data line DL and the first connection electrode CM1 may each include a single-layered structure or a multi-layered structure, each including a conductive material such as Mo, Cu, Ti, and Al. In an embodiment, the data line DL and the first connection electrode CM1 may each include a triple-layered structure of Ti, Al, and Ti (Ti/Al/Ti).

The first connection electrode CM1 may be electrically connected to the first semiconductor layer A1 through a contact hole H1. The contact hole H1 may expose a portion of the first semiconductor layer A1 by penetrating the first insulating layer 111, the second insulating layer 112, the third insulating layer 113, and the fifth insulating layer 115.

A first organic insulating layer 116 may be disposed on the data line DL and the first connection electrode CM1. The first organic insulating layer 116 may include an organic material, such as acrylic, benzocyclobutene (BCB), polyimide, hexamethyldisiloxane (HMDSO), or the like.

A driving voltage line PL and a second connection electrode CM2 may be disposed on the first organic insulating layer 116. The second connection electrode CM2 may be electrically connected to the first connection electrode CM1 through a contact hole H2 defined in the first organic insulating layer 116. The driving voltage line PL and the second connection electrode CM2 may each include a single-layered structure or a multi-layered structure, each including a conductive material such as Mo, Cu, Ti, and Al.

A second organic insulating layer 117 may be disposed on the driving voltage line PL and the second connection electrode CM2. The second organic insulating layer 117 may include an organic material such as acrylic, BCB, polyimide, HMDSO, or the like.

The light-emitting diode LED may be disposed on the second organic insulating layer 117. The light-emitting diode LED may include a pixel electrode 210, an opposite electrode 230 on the pixel electrode 210, and an emission layer 220 between the pixel electrode 210 and the opposite electrode 230.

The pixel electrode 210 may be disposed on the second organic insulating layer 117. The pixel electrode 210 may be electrically connected to the second connection electrode CM2 through a contact hole H3 defined in the second organic insulating layer 117. Accordingly, the pixel electrode 210 may be electrically connected to the first thin-film transistor TFT1 through the first connection electrode CM1 and the second connection electrode CM2. The pixel electrode 210 may include a conductive oxide such as indium tin oxide (ITO), indium zinc oxide (IZO), zinc oxide (ZnO), indium oxide (In₂O₃), indium gallium oxide (IGO), or aluminum zinc oxide (AZO). In an embodiment, the pixel electrode 210 may include a reflective film, the reflective film including silver (Ag), magnesium (Mg), Al, platinum (Pt), palladium (Pd), gold (Au), nickel (Ni), neodymium (Nd), iridium (Ir), chromium (Cr), or a compound thereof. In an embodiment, the pixel electrode 210 may further include a film including ITO, IZO, ZnO, or In₂O₃ above/below the reflective film described above.

A pixel defining layer 118 may be disposed on the second organic insulating layer 117 to cover an edge of the pixel electrode 210. The pixel defining layer 118 may define an opening OP exposing a central portion of the pixel electrode 210. The opening OP may correspond to an emission area of each pixel. The pixel defining layer 118 may prevent an arc or the like from being generated at the edge of the pixel electrode 210 by increasing a distance between the edge of the pixel electrode 210 and the opposite electrode 230. The pixel defining layer 118 may include an organic material, such as polyimide or HMDSO.

The emission layer 220 may be disposed on the pixel electrode 210 to correspond to the opening OP. The emission layer 220 may include a polymer organic material or a low-molecular-weight organic material, which emits light of a certain color. In an embodiment, a first functional layer may be disposed between the pixel electrode 210 and the emission layer 220, and a second functional layer may be disposed between the emission layer 220 and the opposite electrode 230. In an embodiment, the emission layer 220 may be patterned to correspond to the pixel electrode 210. The first functional layer or the second functional layer may include an integrated layer over a plurality of pixel electrodes 210 or may include a patterned layer corresponding to each of the plurality of pixel electrodes 210.

The first functional layer may include a hole transport layer or may include a hole injection layer and a hole transport layer. The second functional layer may include an electron transport layer or an electron injection layer. In an embodiment, at least one of the first functional layer and the second functional layer may be omitted.

The opposite electrode 230 may be disposed to face the pixel electrode 210 with the emission layer 220 between the opposite electrode 230 and the pixel electrode 210. The opposite electrode 230 may include a conductive material having a low work function. The opposite electrode 230 may include a (semi)transparent layer, the (semi)transparent layer including Ag, Mg, Al, Pt, Pd, Au, Ni, Nd, Ir, Cr, lithium (Li), calcium (Ca), alloys thereof, or the like. Alternatively, the opposite electrode 230 may further include a layer, such as ITO, IZO, ZnO, or In₂O₃, above the (semi)transparent layer including the materials stated above. The opposite electrode 230 may be a common electrode integrally formed with the plurality of light-emitting diodes LED. The opposite electrode 230 may cover the display area DA and extend to the non-display area NDA (refer to FIG. 3) to be electrically connected to the second power voltage line 140 (refer to FIG. 3).

A spacer 119 may be disposed on the pixel defining layer 118 to prevent damage caused by the mask. The spacer 119 may include an organic material such as polyimide or HMDSO. The spacer 119 may include the same material as the pixel defining layer 118. In an embodiment, the pixel defining layer 118 and the spacer 119 may be formed through the same process. For example, the pixel defining layer 118 and the spacer 119 may be formed by using a mask in which an area corresponding to the pixel defining layer 118 is provided with a half tone and an area corresponding to the spacer 119 is provided with a full tone.

The encapsulation layer 300 may be disposed on the light-emitting diode LED. In an embodiment, the encapsulation layer 300 may include a first inorganic encapsulation layer 310, an organic encapsulation layer 320, and a second inorganic encapsulation layer 330. The first inorganic encapsulation layer 310 may be disposed on the opposite electrode 230 and include a single-layered structure or a multi-layered structure, each including an inorganic insulating material such as silicon oxide, silicon nitride, or silicon oxynitride. In an embodiment, a capping layer or the like may be disposed between the opposite electrode 230 and the first inorganic encapsulation layer 310. The organic encapsulation layer 320 may include an organic material, such as acrylic, BCB, polyimide, HMDSO, or the like. The second inorganic encapsulation layer 330 may be disposed on the organic encapsulation layer 320 and include a single-layered structure or a multi-layered structure, each including an inorganic insulating material such as silicon oxide, silicon nitride, or silicon oxynitride. The first inorganic encapsulation layer 310 and the second inorganic encapsulation layer 330 may extend to the non-display area NDA (refer to FIG. 3) to be in contact with each other. The first inorganic encapsulation layer 310 and the organic encapsulation layer 320 may prevent or reduce moisture or oxygen from the outside from penetrating into the display area DA through the organic encapsulation layer 320 by forming an inorganic contact.

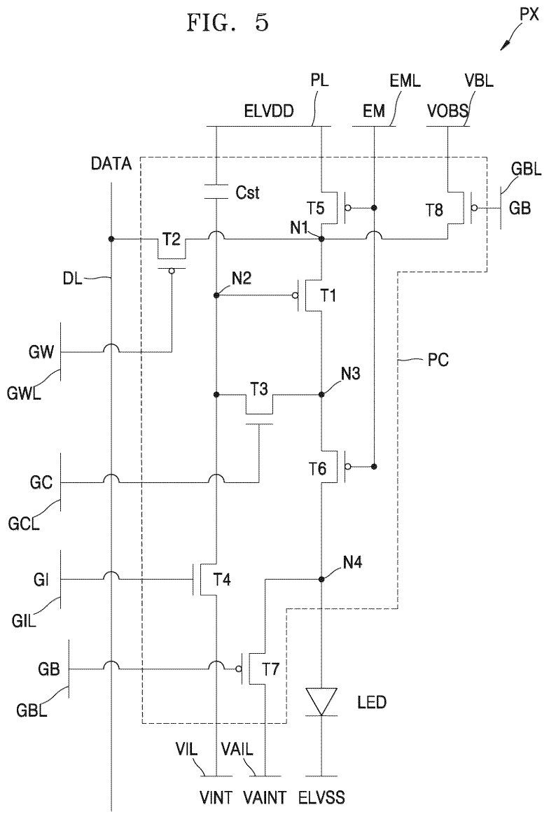

FIG. 5 is a schematic equivalent circuit diagram of a pixel according to an embodiment.

Referring to FIG. 5, the pixel PX may include the light-emitting diode LED and a pixel circuit PC electrically connected to the light-emitting diode LED. The pixel circuit PC may include first to eighth transistors T1 to T8 and a storage capacitor Cst. The pixel circuit PC may be electrically connected to gate lines configured to deliver gate signals, such as a first gate line GWL, a second gate line GIL, a third gate line GCL, a fourth gate line GBL, and an emission control line EML. The pixel circuit PC may be electrically connected to the data line DL configured to deliver data signals. In addition, the pixel circuit PC may be electrically connected to a first initialization voltage line VIL, a second initialization voltage line VAIL, and a driving voltage line PL.

FIG. 5 illustrates that, among the first to eighth transistors T1 to T8, the third transistor T3 and the fourth transistor T4 are N-type transistors, and the remaining transistors T1, T2, T5, T6, T7, and T8 are P-type transistors. In an embodiment, the N-type transistors include oxide-based semiconductor materials, and the P-type transistors may include silicon-based semiconductor materials. For example, the first thin-film transistor TFT1 shown in FIG. 4 may correspond to the sixth transistor T6, and the second thin-film transistor TFT2 may correspond to the third transistor T3 or the fourth transistor T4. According to the type of transistors (N-type or P-type) or operating conditions, a first terminal of a transistor may be one of a source area (source electrode) and a drain area (drain electrode), and a second terminal thereof may be the other one different from the first terminal. For example, when the first terminal is a source area, the second terminal may be a drain area. A gate of the transistor may be a gate electrode.

The first transistor T1 may be connected between the driving voltage line PL and the light-emitting diode LED. The first transistor T1 may include a first terminal electrically connected to a first node N1, a gate electrically connected to a second node N2, and a second terminal electrically connected to a third node N3. The first transistor T1 may be electrically connected to the driving voltage line PL via the fifth transistor T5, and may be electrically connected to the light-emitting diode LED via the sixth transistor T6. The driving voltage line PL may be electrically connected to the first power voltage line 130 (refer to FIG. 3) and may be configured to deliver the first power voltage ELVDD to the first transistor T1. The first transistor T1 may function as a driving transistor that receives a data signal DATA in response to a switching operation of the second transistor T2 and supplies a driving current to the light-emitting diode LED.

The second transistor T2 (data write transistor) may be connected between the data line DL and the first node N1. The second transistor T2 may include a first terminal electrically connected to the data line DL, a gate electrically connected to the first gate line GWL, and a second terminal electrically connected to the first node N1. The second transistor T2 may be turned on in response to a first gate signal GW received through the first gate line GWL and may perform a switching operation of delivering the data signal DATA delivered through the data line DL to the first node N1.

The third transistor T3 (compensation transistor) may be connected between the second node N2 and the third node N3. The third transistor T3 may include a gate electrically connected to the third gate line GCL, a first terminal electrically connected to the second node N2, and a second terminal electrically connected to the third node N3. The third transistor T3 may be turned on in response to a third gate signal GC received through the third gate line GCL to diode-connect the first transistor T1, thereby compensating for a threshold voltage of the first transistor T1.

The fourth transistor T4 (first initialization transistor) may be connected between the first initialization voltage line VIL and the second node N2. The fourth transistor T4 may include a gate electrically connected to the second gate line GIL, a first terminal electrically connected to the second node N2, and a second terminal electrically connected to the first initialization voltage line VIL. The fourth transistor T4 may be turned on in response to a second gate signal GI received through the second gate line GIL and deliver a first initialization voltage Vint to the second node N2 to initialize the gate of the first transistor T1.

The fifth transistor T5 (first emission control transistor) may be connected between the driving voltage line PL and the first node N1. The sixth transistor T6 (second emission control transistor) may be connected between the third node N3 and a fourth node N4. The fifth transistor T5 may have a gate electrically connected to the emission control line EML, a first terminal electrically connected to the driving voltage line PL, and a second terminal electrically connected to the first node N1. Because the driving voltage line PL is electrically connected to the first power voltage line 130 (refer to FIG. 3), the fifth transistor T5 may also be indicated as being connected between the first power voltage line 130 and the first node N1. The sixth transistor T6 may include a gate electrically connected to the emission control line EML, a first terminal electrically connected to the third node N3, and a second terminal electrically connected to the fourth node N4. Because a pixel electrode of the light-emitting diode LED is electrically connected to the fourth node N4, the second terminal of the sixth transistor T6 may be indicated as being electrically connected to the light-emitting diode LED. The fifth transistor T5 and the sixth transistor T6 may be simultaneously turned on in response to an emission control signal EM received through the emission control line EML, and thus, a driving current may flow through the light-emitting diode LED.

The seventh transistor T7 (second initialization transistor) may be connected between the second initialization voltage line VAIL and the fourth node N4. The seventh transistor T7 may include a gate electrically connected to the fourth gate line GBL, a first terminal electrically connected to the fourth node N4, and a second terminal electrically connected to the second initialization voltage line VAIL. The seventh transistor T7 may be turned on in response to a fourth gate signal GB received through the fourth gate line GBL and configured to deliver a second initialization voltage VAINT to the fourth node N4 to initialize the pixel electrode of the light-emitting diode LED. In an embodiment, the first initialization voltage Vint and the second initialization voltage VAINT may be different from each other. In another embodiment, the second initialization voltage line VAIL may be omitted, and the gate of the seventh transistor T7 may be electrically connected to the first initialization voltage line VIL.

The eighth transistor T8 (bias transistor) may be connected between the first node N1 and a bias voltage line VBL. The eighth transistor T8 may include a gate electrically connected to the fourth gate line GBL, a first terminal electrically connected to the bias voltage line VBL, and a second terminal electrically connected to the first node N1. The eighth transistor T8 may be turned on in response to the fourth gate signal GB received through the fourth gate line GBL and apply a bias voltage VOBS to the first node N1 to set a voltage suitable for a subsequent operation of the first transistor T1 at the first terminal. The seventh transistor T7 and the eighth transistor T8 may be substantially simultaneously turned on and off according to the fourth gate signal GB. In an embodiment, a level of the bias voltage VOBS may be higher than a level of the first power voltage ELVDD. For example, the first power voltage ELVDD may be about 3.3 V, and the bias voltage VOBS may be about 5.0 V.

The storage capacitor Cst may include a first electrode connected to the gate of the first transistor T1 and a second electrode connected to the driving voltage line PL. The storage capacitor Cst may maintain a voltage applied to the gate of the first transistor T1 by storing and maintaining a voltage corresponding to the difference between voltages of both ends of the driving voltage line PL and the gate of the first transistor T1.

The light-emitting diode LED may include the pixel electrode 210 (refer to FIG. 4) and the opposite electrode 230 (refer to FIG. 4), and the opposite electrode 230 may receive the second power voltage ELVSS from the second power voltage line 140 (refer to FIG. 3). The light-emitting diode LED may emit light having a brightness corresponding to the data signal DATA by receiving a driving current from the first transistor T1.

FIG. 5 illustrates that the pixel circuit PC includes eight transistors and one capacitor, but the disclosure is not limited thereto. The number of transistors and capacitors included in the pixel circuit PC may be designed and changed in various ways.

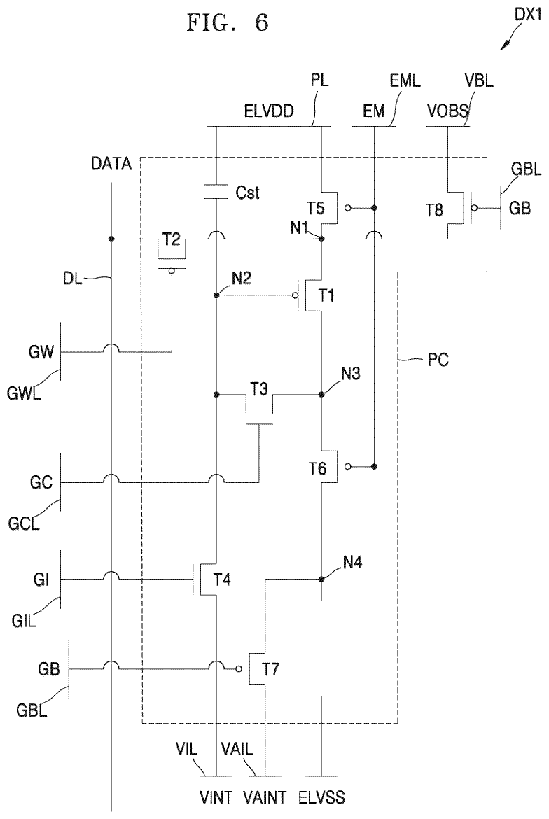

FIG. 6 is a schematic equivalent circuit diagram of a first dummy pixel according to an embodiment.

Referring to FIG. 6, a first dummy pixel DX1 may include a first dummy circuit DC1. The first dummy pixel DX1 may not include a display element. In an embodiment, the first dummy circuit DC1 is electrically connected to a dummy pixel electrode, but the dummy pixel electrode may not function as a display element by being electrically insulated by the opposite electrode 230 (refer to FIG. 3) and at least one insulating layer (e.g., the pixel defining layer 118).

The first dummy circuit DC1 may have substantially the same configuration as the pixel circuit PC. For example, the first dummy circuit DC1 may include first to eighth transistors T1 to T8 and the storage capacitor Cst. The first dummy circuit DC1 may be electrically connected to gate lines configured to deliver gate signals, such as the first gate line GWL, the second gate line GIL, the third gate line GCL, the fourth gate line GBL, and the emission control line EML. The first dummy circuit DC1 may be electrically connected to the data line DL configured to deliver data signals. In addition, the first dummy circuit DC1 may be electrically connected to the first initialization voltage line VIL, the second initialization voltage line VAIL, and the driving voltage line PL. Hereinafter, configurations that are identical or similar to the pixel circuit PC are omitted, and differences are mainly described.

The first transistor T1 may include a first terminal electrically connected to the first node N1, a gate electrically connected to the second node N2, and a second terminal electrically connected to the third node N3. The second transistor T2 may be connected between the data line DL and the first node N1, and a gate of the second transistor T2 may be electrically connected to the first gate line GWL. The third transistor T3 may be connected between the second node N2 and the third node N3, and a gate of the third transistor T3 may be electrically connected to the third gate line GCL. The fourth transistor T4 may be connected between the first initialization voltage line VIL and the second node N2, and a gate of the fourth transistor T4 may be electrically connected to the second gate line GIL. The seventh transistor T7 may be connected between the second initialization voltage line VAIL and the fourth node N4, and a gate of the seventh transistor T7 may be electrically connected to the fourth gate line GBL. The eighth transistor T8 may be connected between the bias voltage line VBL and the first node N1, and a gate of the eighth transistor T8 may be electrically connected to the fourth gate line GBL.

The fifth transistor T5 may be connected between the driving voltage line PL and the first node N1. The sixth transistor T6 may be connected between the third node N3 and the fourth node N4. The fifth transistor T5 may have a gate electrically connected to the emission control line EML, a first terminal electrically connected to the driving voltage line PL, and a second terminal electrically connected to the first node N1. The sixth transistor T6 may include a gate electrically connected to the emission control line EML, a first terminal electrically connected to the third node N3, and a second terminal electrically connected to the fourth node N4.

The first dummy pixel DX1 may not include the light-emitting diode LED, and the fourth node N4 of the first dummy pixel DX1 may be electrically insulated to a component configured to deliver the second power voltage ELVSS, for example, the opposite electrode 230 (refer to FIG. 4). The fifth transistor T5 and the sixth transistor T6 may be simultaneously turned on in response to the emission control signal EM received through the emission control line EML, but the fourth node N4 is electrically insulated from the opposite electrode 230, and thus a current path from the first power voltage ELVDD to the second power voltage ELVSS is not formed.

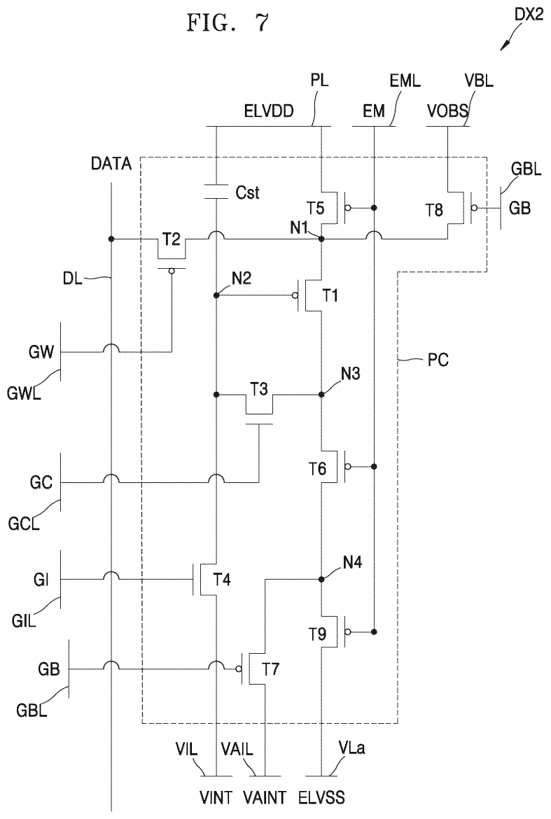

FIG. 7 is a schematic equivalent circuit diagram of a second dummy pixel according to an embodiment.

Referring to FIG. 7, a second dummy pixel DX2 may include a second dummy circuit DC2. The second dummy circuit DC2 is similar to the pixel circuit PC but does include a display element, and differs in that the fourth node N4 is electrically connected to an auxiliary voltage line VLa via a ninth transistor T9.

The second dummy circuit DC2 may include first to ninth transistors T1 to T9 and a storage capacitor Cst. The second dummy circuit DC2 may be electrically connected to gate lines configured to deliver gate signals, such as the first gate line GWL, the second gate line GIL, the third gate line GCL, the fourth gate line GBL, and the emission control line EML. The second dummy circuit DC2 may be electrically connected to the data line DL configured to deliver data signals. Also, the second dummy circuit DC2 may be electrically connected to the first initialization voltage line VIL, the second initialization voltage line VAIL, and the driving voltage line PL. Hereinafter, configurations that are identical or similar to the pixel circuit PC are omitted, and differences are mainly described.

The first transistor T1 may include a first terminal electrically connected to the first node N1, a gate electrically connected to the second node N2, and a second terminal electrically connected to the third node N3. The second transistor T2 may be connected between the data line DL and the first node N1, and a gate of the second transistor T2 may be electrically connected to the first gate line GWL. The third transistor T3 may be connected between the second node N2 and the third node N3, and a gate of the third transistor T3 may be electrically connected to the third gate line GCL. The fourth transistor T4 may be connected between the first initialization voltage line VIL and the second node N2, and a gate of the fourth transistor T4 may be electrically connected to the second gate line GIL. The seventh transistor T7 may be connected between the second initialization voltage line VAIL and the fourth node N4, and a gate of the seventh transistor T7 may be electrically connected to the fourth gate line GBL. The eighth transistor T8 may be connected between the bias voltage line VBL and the first node N1, and a gate of the eighth transistor T8 may be electrically connected to the fourth gate line GBL.

The fifth transistor T5 may be connected between the driving voltage line PL and the first node N1. The sixth transistor T6 may be connected between the third node N3 and the fourth node N4. The fifth transistor T5 may have a gate electrically connected to the emission control line EML, a first terminal electrically connected to the driving voltage line PL, and a second terminal electrically connected to the first node N1. The sixth transistor T6 may include a gate electrically connected to the emission control line EML, a first terminal electrically connected to the third node N3, and a second terminal electrically connected to the fourth node N4.

The ninth transistor T9 may be connected between the fourth node N4 and the auxiliary voltage line VLa. The ninth transistor T9 may include a first terminal electrically connected to the fourth node N4, a gate electrically connected to the emission control line EML, and a second terminal electrically connected to the auxiliary voltage line VLa. Here, the auxiliary voltage line VLa may be a line electrically connected to the second power voltage line 140 (refer to FIG. 3) or the opposite electrode 230 (refer to FIG. 4) and configured to deliver the second power voltage ELVSS. The auxiliary voltage line VLa is electrically connected to the second power voltage line 140, and thus the ninth transistor T9 may be indicated as being electrically connected to the second power voltage line 140.

The fifth transistor T5, the sixth transistor T6, and the ninth transistor T9 may be simultaneously turned on in response to the emission control signal EM received through the emission control line EML to form a sink-current path electrically connecting the first power voltage line 130 (refer to FIG. 3) to the second power voltage line 140.

Referring to FIG. 3 together, the display apparatus 10 may include the dummy pixels DX disposed in the first non-display area NDA1 outside the display area DA. The dummy pixels DX may include the first dummy pixels DX1 described above with reference to FIG. 6 and at least one second dummy pixel DX2 described above with reference to FIG. 7. When the first transistor T1 of the pixels PX is turned off and the eighth transistor T8 is turned on when the display apparatus 10 displays black, a voltage of the first node N1 may increase due to the bias voltage VOBS. Because a level of the bias voltage VOBS is higher than a level of the first power voltage ELVDD, when the fifth transistor T5 is turned on by the emission control signal EM, the level of the first power voltage ELVDD may be higher than a preset level by the voltage of the first node N1. At this time, the second dummy pixel DX2 may operate as a sink-current path electrically connecting the first power voltage line 130 to the second power voltage line 140 to restore the level of the first power voltage ELVDD.

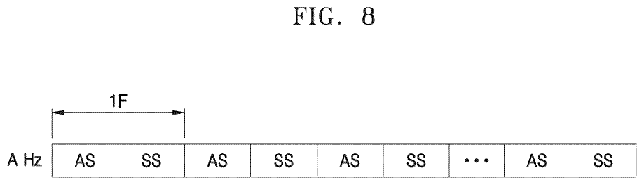

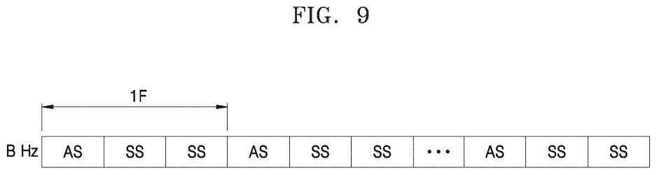

FIGS. 8 and 9 are conceptual diagrams for describing a method of driving a display apparatus according to a driving frequency.

Referring to FIGS. 8 and 9, the display apparatus 10 (refer to FIG. 1) may support a variable refresh rate. The display apparatus 10 may operate by changing a driving frequency within a range of a maximum driving frequency and a minimum driving frequency.

Depending on the driving frequency, one frame 1F may include a first scan period AS or may include the first scan period AS and one or more second scan periods SS. For example, as shown in FIG. 8, in the display apparatus 10 operating at a driving frequency of A Hz, one frame 1F may include one first scan period AS and one second scan period SS. As shown in FIG. 9, in the display apparatus 10 operating at a driving frequency of B Hz less than A Hz, one frame 1F may include one first scan period AS and two or more second scan periods SS. As the driving frequency is lowered, the length of one frame 1F may be longer.

The first scan period AS may be an address scan period in which the data signal DATA (refer to FIG. 5) is written to the pixel PX, and the pixel PX emits light having a brightness corresponding to the written data signal DATA. An operation in which the data signal DATA is written from the data line DL (refer to FIG. 5) to the pixel circuit PC (refer to FIG. 5) of the pixel PX may be referred to as a data programming operation.

The second scan period SS may be a self scan period in which the data signal DATA is not written to the pixel PX. During the second scan period SS, the data signal DATA written in the first scan period AS may be maintained, and the pixel PX may emit light having a brightness corresponding to the data signal DATA written in the first scan period AS. A length of the second scan period SS may be substantially the same as a length of the first scan period AS.

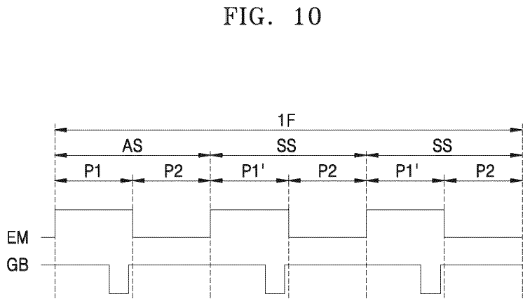

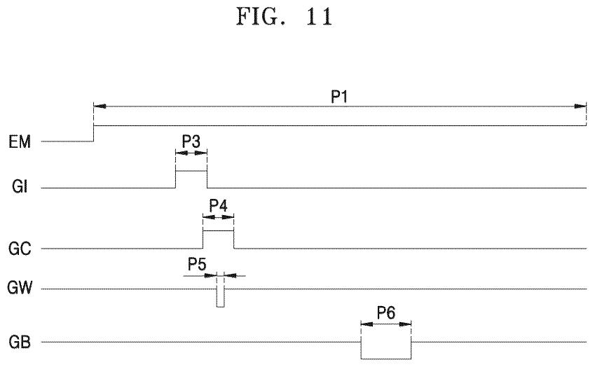

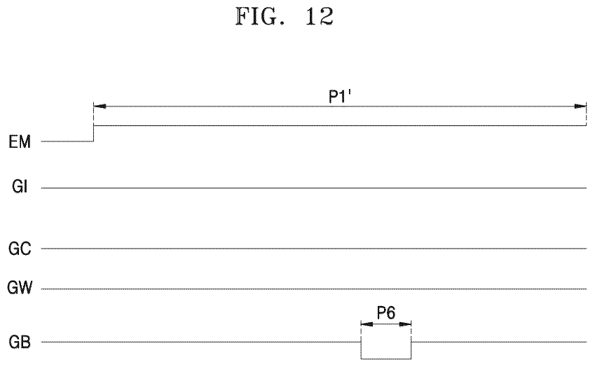

FIG. 10 is a schematic timing diagram of signals supplied during a first scan period and a second scan period. FIG. 11 is a schematic timing diagram of signals supplied during a non-emission period of the first scan period. FIG. 12 is a schematic timing diagram of signals supplied during a non-emission period of the second scan period.

Referring to FIGS. 5 to 7 and 10 to 12 together, the first scan period AS may include a non-emission period P1 and an emission period P2. During the non-emission period P1 of the first scan period AS, the emission control signal EM may be supplied as a gate-off voltage, and during the emission period P2, the emission control signal EM may be supplied as a gate-on voltage. During the non-emission period P1 of the first scan period AS, the data signal DATA corresponding to each of the pixel circuit PC, the first dummy circuit DC1, and the second dummy circuit DC2 may be written. During the emission period P2, the pixel PX may emit light having a brightness corresponding to the written data signal DATA. During the emission period P2, the second dummy pixel DX2 may operate as a sink-current path. At this time, the first dummy pixel DX1 is electrically separated from the opposite electrode 230 (refer to FIG. 4), and thus the first dummy pixel DX1 may not form a driving current path.

As shown in FIG. 11, during the non-emission period P1 of the first scan period AS, the emission control signal EM of a gate-off signal may be supplied to the emission control line EML. The non-emission period P1 of the first scan period AS may include a first initialization period P3, a compensation period P4, a data write period P5, and a second initialization-compensation period P6.

In the first initialization period P3, the second gate signal GI of a gate-on voltage may be supplied to the second gate line GIL. The first gate signal GW, the third gate signal GC, and the fourth gate signal GB, which are gate-off voltages, may be respectively supplied to the first gate line GWL, the third gate line GCL, and the fourth gate line GBL. The fourth transistor T4 may be turned on by the second gate signal GI, and the gate of the first transistor T1 may be initialized to the first initialization voltage Vint.

In the compensation period P4, the third gate signal GC of a gate-on voltage may be supplied to the third gate line GCL. The compensation period P4 may partially overlap the first initialization period P3. For example, the second gate signal GI of the gate-on voltage may be supplied to the second gate line GIL at the start of the compensation period P4, and then the second gate signal GI may be changed to a gate-off voltage at an end point of the first initialization period P3. The third transistor T3 may be turned on by the third gate signal GC, and the first transistor T1 may be diode-connected.

The data write period P5 may overlap the compensation period P4. In the data write period P5, the first gate signal GW of the gate-on voltage may be supplied to the first gate line GWL. The data signal DATA may be supplied to the first node N1 by the second transistor T2 which is turned on. Because the first transistor T1 is diode-connected by the third transistor T3 which is turned on, a compensation voltage obtained by compensating a threshold voltage of the first transistor T1 from the data signal DATA may be applied to the second node N2, that is, the gate of the first transistor T1. Accordingly, the first power voltage ELVDD and the compensation voltage may be applied to both ends of the storage capacitor Cst, and a charge corresponding to the voltage difference between the both ends may be stored in the storage capacitor Cst. An end point of the compensation period P4 may be later than the data write period P5.

In the second initialization-compensation period P6, the fourth gate signal GB of the gate-on voltage may be supplied to the fourth gate line GBL. The first gate signal GW, the second gate signal GI, and the third gate signal GC, which are gate-off signals, may be respectively supplied to the first gate line GWL, the second gate line GIL, and the third gate line GCL. The seventh transistor T7 may be turned on by the fourth gate signal GB, and the fourth node N4 may be initialized to the second initialization voltage VAINT. The eighth transistor T8 may be turned on by the fourth gate signal GB, and the bias voltage VOBS may be supplied to the first node N1.

In the emission period P2, the emission control signal EM of the gate-on voltage may be supplied to the emission control line EML. The first gate signal GW, the second gate signal GI, the third gate signal GC, and the fourth gate signal GB, which are gate-off voltages, may be respectively supplied to the first gate line GWL, the second gate line GIL, the third gate line GCL, and the fourth gate line GBL.

The second scan period SS may include a non-emission period P1′ and the emission period P2. During the non-emission period P1′ of the second scan period SS, the emission control signal EM may be supplied as a gate-off voltage, and during the emission period P2, the emission control signal EM may be supplied as a gate-on voltage. During the non-emission period P1′ of the second scan period SS, the data signal DATA may not be newly written to each of the pixel circuit PC, the first dummy circuit DC1, and the second dummy circuit DC2. During the emission period P2, the pixel PX may emit light having a brightness corresponding to the data signal DATA written in the first scan period AS, and the second dummy pixel DX2 may operate as a sink-current path.

As shown in FIG. 12, during the non-emission period P1′ of the second scan period SS, the first gate signal GW, the second gate signal GI, the third gate signal GC, and the emission control signal EM, which are gate-off voltages, may be respectively supplied to the first gate line GWL, the second gate line GIL, the third gate line GCL, and the emission control line EML. The non-emission period P1′ may include a second initialization-compensation period P6. In the second initialization-compensation period P6, the fourth gate signal GB of a gate-on voltage may be supplied to the fourth gate line GBL. The seventh transistor T7 may be turned on by the fourth gate signal GB, and the fourth node N4 may be initialized to the second initialization voltage VAINT. The eighth transistor T8 may be turned on by the fourth gate signal GB, and the bias voltage VOBS may be supplied to the first node N1.

During the emission period P2 of the second scan period SS, the emission control signal EM of the gate-on voltage may be supplied to the emission control line EML. The first gate signal GW, the second gate signal GI, the third gate signal GC, and the fourth gate signal GB, which are gate-off voltages, may be respectively supplied to the first gate line GWL, the second gate line GIL, the third gate line GCL, and the fourth gate line GBL.

During the emission period P2 of the first scan period AS and the emission period P2 of the second scan period SS, the light-emitting diode LED of the pixel PX may emit light having a brightness corresponding to the data signal DATA written in the first scan period AS.

During the emission period P2 of the first scan period AS and the emission period P2 of the second scan period SS, the ninth transistor T9 of the second dummy pixel DX2 may be turned on by the emission control signal EM. The fifth transistor T5, the sixth transistor T6, and the ninth transistor T9, which are turned on by the emission control signal EM, may electrically connect the driving voltage line PL to the auxiliary voltage line VLa. The driving voltage line PL may be electrically connected to the first power voltage line 130 (refer to FIG. 3), and the auxiliary voltage line VLa may be electrically connected to the second power voltage line 140 (refer to FIG. 4). Accordingly, the fifth transistor T5, the sixth transistor T6, and the ninth transistor T9, which are turned on, may operate as a sink-current path electrically connecting the first power voltage line 130 to the second power voltage line 140.

During the second initialization-compensation period P6, the eighth transistor T8 may be turned on, and the bias voltage VOBS may be supplied to the first node N1. The level of the bias voltage VOBS may be higher than the level of the first power voltage ELVDD. When the display apparatus 10 displays black, even during the emission period P2, the first transistor T1 may be turned off, and substantially no current may flow or a relatively small current may flow. The first node N1 is electrically connected to the driving voltage line PL through the fifth transistor T5 which is turned on in response to the emission control signal EM, and thus the level of the first power voltage ELVDD may be increased above a preset value.

As shown in FIG. 10, the fourth gate signal GB may be supplied as a gate-on voltage at least once every first scan period AS and second scan period SS. The second scan period SS only includes the second initialization-compensation period P6 and does not include the first initialization period P3 and the compensation period P4, and thus a brightness difference may increase due to an increase in the level of the first power voltage ELVDD when being driven at a low frequency. The second dummy pixel DX2 according to an embodiment may form a sink-current path that flows from the first power voltage ELVDD to the second power voltage ELVSS based on the emission control signal EM, thereby restoring the first power voltage ELVDD to a preset value at every emission period P2.

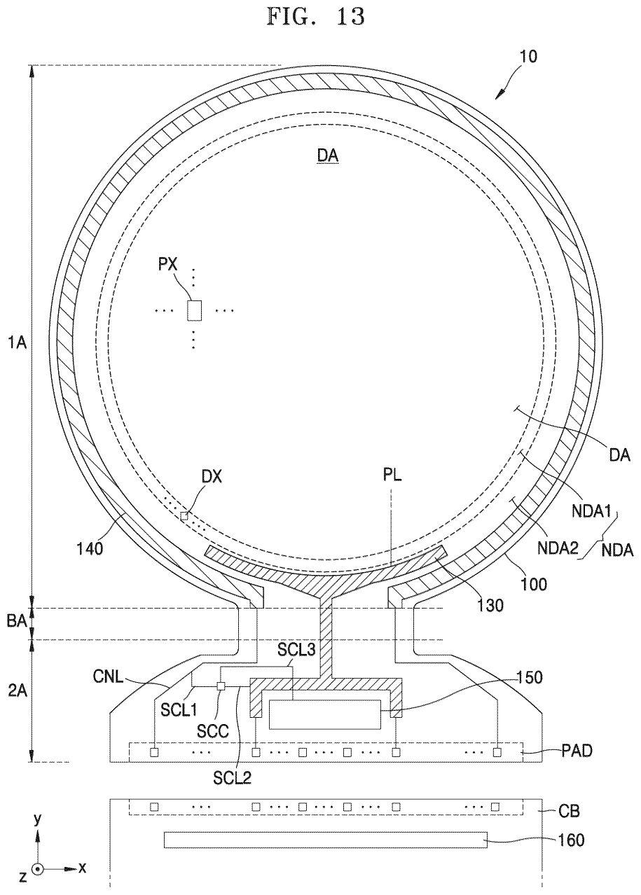

FIG. 13 is a schematic plan view of a display apparatus according to an embodiment.

Referring to FIG. 13, the display apparatus 10 may include the substrate 100. The substrate 100 may include a first area 1A, a second area 2A, and a bending area BA. Also, the substrate 100 may include a display area DA and a non-display area NDA outside the display area DA. The first area 1A may be a display portion displaying an image by overlapping the display area DA. The second area 2A may be disposed outside the first area 1A and extend to one side of the first area 1A (e.g., a bottom side, in a-y direction). The bending area BA may be disposed between the first area 1A and the second area 2A.

Pixels PX may be disposed in the display area DA. Each of the pixels PX may include a pixel circuit PC and a light-emitting diode LED electrically connected to the pixel circuit PC, as shown in FIG. 5.

The non-display area NDA may include a first non-display area NDA1 adjacent to the display area DA and a second non-display area NDA2 outside the first non-display area NDA1. Dummy pixels DX may be disposed in the first non-display area NDA1. Each of the dummy pixels DX may be the first dummy pixel DX1 shown in FIG. 6. The dummy pixel DX indicates a sub-pixel that includes the first dummy circuit DC1 that has a configuration substantially identical or similar to the pixel circuit PC but does not include a display element and thus does not emit light.

The first power voltage line 130 and the second power voltage line 140 may be disposed in the second non-display area NDA2 of the first area 1A. The gate driving circuit 13 (refer to FIG. 1) may be disposed in the second non-display area NDA2. The first power voltage line 130 may be electrically connected to the driving voltage lines PL configured to deliver the first power voltage ELVDD (refer to FIG. 5) to the pixels PX and the dummy pixels DX disposed in the display area DA. The first power voltage line 130 may be electrically connected to a pad of the pad unit PAD. The second power voltage line 140 may be electrically connected to the opposite electrode 230 (refer to FIG. 4) of the pixels PX disposed in the display area DA and electrically connected to the pad of the pad unit PAD through the connection line CNL. The second power voltage line 140 may be configured to deliver the second power voltage ELVSS (refer to FIG. 5) to the opposite electrode 230 of the pixels PX.

A first driving integrated circuit 150 may be disposed in the second area 2A of the substrate 100. The first driving integrated circuit 150 may be directly disposed on an upper portion of the substrate 100 in a COG or COP method. In an embodiment, the first driving integrated circuit 150 may include the controller 19 (refer to FIG. 1). For example, the first driving integrated circuit 150 may generate control signals based on signals input from the outside and supply the generated control signals to the gate driving circuit 13 (refer to FIG. 1), the data driving circuit 15 (refer to FIG. 1), the power supply circuit 17 (refer to FIG. 1), and a sink circuit SCC. The control signals may include a plurality of clock signals, gate start signals, and data start signals.

The sink circuit SCC may be disposed in the second area 2A. The sink circuit SCC may be electrically connected to the connection line CNL through a first sink line SCL1, electrically connected to the first power voltage line 130 through a second sink line SCL2, and electrically connected to the first driving integrated circuit 150 through a third sink line SCL3. The sink circuit SCC may operate as a sink-current path electrically connecting the first power voltage line 130 to the second power voltage line 140 based on a sink-control signal output by the first driving integrated circuit 150.

The sink circuit SCC may be disposed to be adjacent to the first driving integrated circuit 150 (or the controller 19). For example, the first driving integrated circuit 150 may be disposed between the first power voltage line 130 and the pad unit PAD, and the sink circuit SCC may be disposed between the connection line CNL and the first power voltage line 130 to be adjacent to the first driving integrated circuit 150.

The display apparatus 10 may further include a circuit board CB. The circuit board CB may be connected to the pad unit PAD of the substrate 100. The second driving integrated circuit 160 may be disposed in the circuit board CB. The second driving integrated circuit 160 may include the power supply circuit 17 (refer to FIG. 1). The second driving integrated circuit 160 may generate and supply the first power voltage ELVDD to the first power voltage line 130 and may generate and supply the second power voltage ELVSS to the second power voltage line 140.

FIG. 13 illustrates that the first driving integrated circuit 150 is disposed in the substrate 100, and the second driving integrated circuit 160 is disposed in the circuit board CB, but the disclosure is not limited thereto. In another embodiment, the first driving integrated circuit 150 and the second driving integrated circuit 160 may be disposed in the circuit board CB. In another embodiment, the circuit board CB may be omitted, and the first driving integrated circuit 150 and the second driving integrated circuit 160 may be directly disposed on the substrate 100 in a COG or COP method.

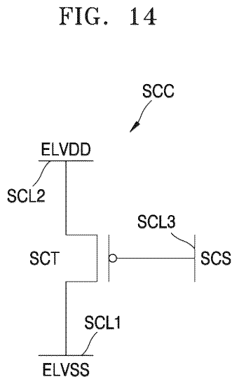

FIG. 14 is a schematic equivalent circuit diagram of a sink circuit according to an embodiment.

Referring to FIG. 14, the sink circuit SCC may include a sink-transistor SCT. The sink circuit SCC may be electrically connected to the first sink line SCL1, the second sink line SCL2, and the third sink line SCL3.

FIG. 14 illustrates that the sink-transistor SCT is a P-type transistor, but the disclosure is not limited thereto. In an embodiment, the sink-transistor SCT may be an N-type transistor. According to the type of transistors (N-type or P-type), a first terminal of a transistor may be one of a source area (source electrode) and a drain area (drain electrode), and a second terminal thereof may be the other one different from the first terminal. For example, when the first terminal is a drain area, the second terminal may be a source area. A gate of the transistor may be a gate electrode.

The sink-transistor SCT may be connected between the first sink line SCL1 and the second sink line SCL2. A first terminal of the sink-transistor SCT may be electrically connected to the first sink line SCL1, a second terminal of the sink-transistor SCT may be electrically connected to the second sink line SCL2, and a gate of the sink-transistor SCT may be electrically connected to the third sink line SCL3.

The first sink line SCL1 may be electrically connected to an exterior voltage line (or a first voltage line) configured to deliver a low-level voltage. The low-level voltage refers to a voltage of 0 V or less, such as the second power voltage ELVSS, the first initialization voltage VINT (refer to FIG. 5), and the second initialization voltage VAINT (refer to FIG. 5). For example, the exterior voltage line may be the second power voltage line 140 (refer to FIG. 13). FIGS. 13 and 14 illustrate that the first sink line SCL1 is electrically connected to the connection line CNL configured to deliver the second power voltage ELVSS to the second power voltage line 140, but the disclosure is not limited thereto. In another embodiment, the exterior voltage line may be a line electrically connected to the first initialization voltage line VIL or the second initialization voltage line VAIL.

The second sink line SCL2 may be electrically connected to the first power voltage line 130 (refer to FIG. 13) configured to transmit the first power voltage ELVDD, and the third sink line SCL3 may be electrically connected to the first driving integrated circuit 150 (refer to FIG. 13). The first driving integrated circuit 150 may include the controller 19 (refer to FIG. 1). The first driving integrated circuit 150 may output a sink-control signal SCS to the third sink line SCL3. The sink-control signal SCS may be a signal including a gate-on voltage that may turn on a transistor and a gate-off transistor (or a ground voltage) that may turn off the transistor. When the display apparatus 10 (refer to FIG. 1) displays black, a signal width of the sink-control signal SCS may be determined based on a current flowing from the first power voltage ELVDD to the second power voltage ELVSS.

The sink-transistor SCT may be turned on when the sink-control signal SCS is supplied as a gate-on voltage to electrically connect the first power voltage line 130 to the exterior voltage line. Accordingly, the sink-transistor SCT may operate as a sink-current path flowing from the first power voltage ELVDD to a low-level voltage. Accordingly, as described above with reference to FIGS. 10 to 12, a brightness difference of the display apparatus 10 over time may be prevented or reduced by restoring the first power voltage ELVDD increased by the bias voltage VOBS (refer to FIG. 5).

The display apparatus 10 (refer to FIG. 1) according to embodiments may be applied to various electronic devices. An electronic device according to an embodiment may include the display apparatus 10 described above, and may further include a module or device having additional functions in addition to the display apparatus 10.

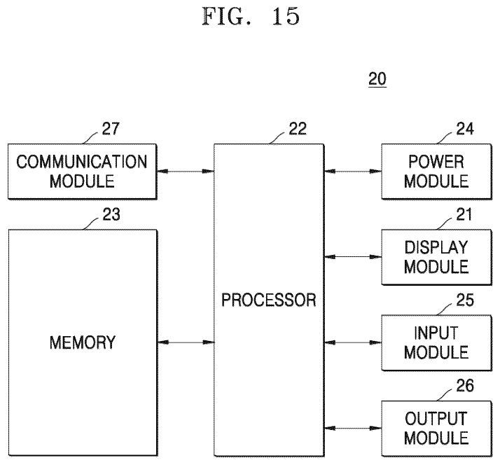

FIG. 15 is a block diagram of an electronic device according to an embodiment.

Referring to FIG. 15, an electronic device 20 according to an embodiment may include a display module 21, a processor 22, a memory 23, and a power module 24. The electronic device 20 may further include an input module 25, a non-image output module 26, or a communication module 27. The processor 22 may be implemented by more than one processor.

The electronic device 20 may output various pieces of information in a form of images through the display module 21. When the processor 22 executes an application stored in the memory 23, image information provided by the application may be provided to a user through the display module 21. The power module 24 may include a power supply module, such as a power adapter or a battery device, and a power conversion module that generates power necessary for an operation of the electronic device 20 by converting power supplied by the power supply module. The input module 25 may provide input information to the processor 22 or the display module 21. The non-image output module 26 may serve to receive information other than images received from the processor 22, such as sound, haptics, and light emission, and provide the information to the user. The communication module 27 is a module responsible for transmitting and receiving information between the electronic device 20 and an external device, which may include a transmission unit and a reception unit.

In an embodiment, the processor 22 may be divided into two or more to be provided from a functional or structural perspective. For example, the processor 22 may include a main processor in a form of a first drive chip including a central processing unit, and an auxiliary processor in a form of a second drive chip including a controller that receives an image signal from the main processor and processes the image signal to match interface specifications of the display module 21.

The memory 23 may include at least one of non-volatile memory and volatile memory. Data information necessary for an operation of the processor 22 or the display module 21 may be stored in the memory 23. When the processor 22 executes an application stored in the memory 23, an image data signal or an input control signal may be transmitted to the display module 21, and the display module 21 may process the received signal and output image information through a display screen.

The power module 24 may include the power supply module, such as a power adapter or a battery device, and the power conversion module that generates power necessary for an operation of the electronic device 20 by converting power supplied by the power supply module. Power conversion by the power conversion module may include direct current (DC)-DC conversion, alternating current (AC)-DC conversion, and DC-AC conversion, but is not limited thereto.

The input module 25 may provide input information to the processor 22 or the display module 21. The input module 25 may include various types of sensor modules as well as a physical button, a keyboard, and a microphone. Examples of the sensor modules may include a touch sensor, a pressure sensor, a distance sensor, a position sensor, a digitizer, a motion recognition sensor, a light receiving sensor, a photoelectric conversion sensor, a temperature sensor, as well as a biometric sensor, such as a blood pressure sensor, a blood sugar sensor, an electrocardiogram sensor, a heart rate sensor, or the like.

The non-image output module 26 may serve to receive information other than an image received from the processor 22 and provide the received information to the user. Examples of the non-image output modules 26 may include an audio module, a haptic module, a light-emitting module, or the like, and may include other functional modules unique to the electronic device (e.g., a cooling module or the like of a refrigerator).

The communication module 27 is a module responsible for transmitting and receiving information between the electronic device 20 and an external device, which may include a transmission unit and a reception unit. The communication module 27 may include various types of wireless communication modules, such as a mobile communication module, a Wi-Fi module, a Bluetooth module, or may include various types of wired communication modules.

At least one of the configurations of the electronic device 20 described above may be included in the display apparatus 10 (refer to FIG. 1) according to the embodiments described above. In addition, some of the individual modules functionally included within a module may be included in the display apparatus 10, and the others may also be provided separately from the display apparatus 10. For example, the display apparatus 10 may include the display module 21, and the processor 22, the memory 23, and the power module 24 may be provided in a form of other devices within the electronic device 20 instead of the display apparatus 10. As another example, the power module 24 may be provided within the display apparatus 10 and may also supply power to the processor 22 and the memory 23 provided within the electronic device 20 instead of the display apparatus 10, but the disclosure is not limited thereto.

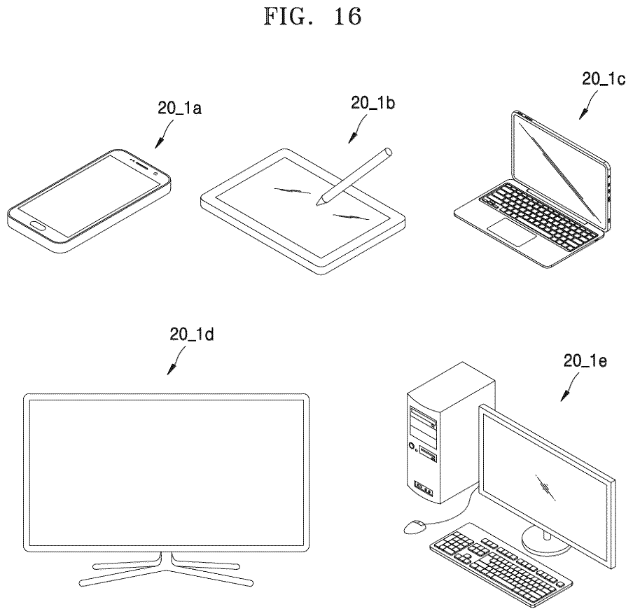

FIGS. 16 to 18 are schematic diagrams of electronic devices according to various embodiments.

FIGS. 16 to 18 illustrate examples of various electronic devices to which the display apparatus 10 (refer to FIG. 1) according to embodiments is applied.

FIG. 16 shows a smartphone 20_1a, a tablet personal computer (PC) 20_1b, a laptop 20_1c, a television (TV) 20_1d, and a desk monitor 20_1e, as examples of an electronic device.

The smartphone 20_1a may include an input module, such as a touch sensor, and a communication module, in addition to a display module. The smartphone 20_1a may process information received through the communication module or other input modules and display the information through a display module of a display apparatus.

Similarly to the smartphone 20_1a, the tablet PC 20_1b, the laptop 20_1c, the TV 20_1d and the desk monitor 20_1e may each include a display module and an input module, and may further include a communication module in some cases.

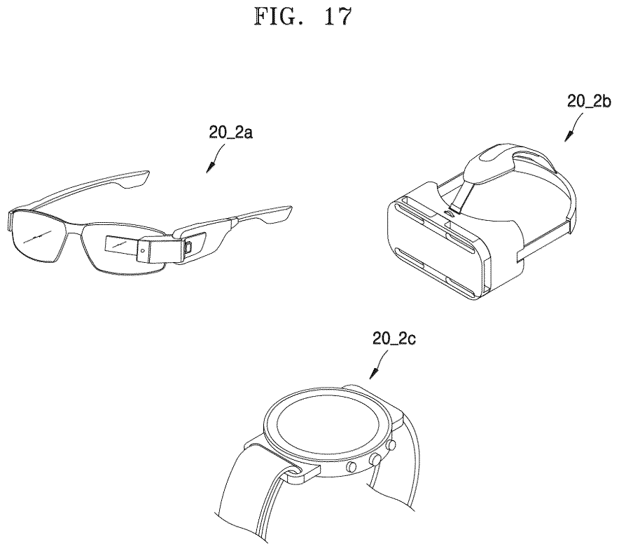

FIG. 17 illustrates an example in which an electronic device including a display module is applied to a wearable electronic device. A wearable electronic device may include smart glasses 20_2a, a head-mounted display 20_2b, and a smartwatch 20_2c.

The smart glasses 20_2a and the head-mounted display 20_2b may include a display module emitting a display image and a reflector reflecting the emitted display image to provide the same to a user's eyes, thereby providing the user with a virtual reality or augmented reality screen.

The smartwatch 20_2c may include a biometric sensor as an input device and provide the user with biometric information recognized by the biometric sensor through the display module.

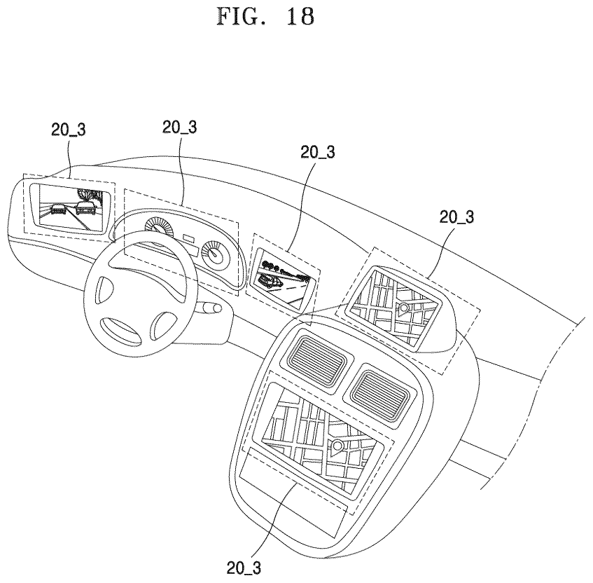

FIG. 18 illustrates an example in which an electronic device including a display module is applied to a vehicle. For example, an electronic device 20_3 may be applied to a dashboard, a center fascia or the like of a vehicle, a center information display (CID) disposed on the dashboard of the vehicle, a room-mirror display or the like replacing a side mirror.

Although not illustrated in the drawings, the electronic devices to which the display apparatus 10 according to embodiments is applied may include various home appliances that display information through display modules, such as refrigerators, a washing machines, dryers, air-conditioners, and robot vacuum cleaners, as well as devices mainly displaying screens, such as billboard electronic boards, game consoles, or the like. In addition, when the display module has a function of transmitting light, the display module may be applied to electronic devices, such as smart windows or transparent display apparatuses displaying a background and a display image together. Types of electronic devices according to embodiments are not limited thereto, and application of various other electronic devices which are not described as examples may also be possible.

According to embodiments described above, a display apparatus displaying high-quality images and an electronic device including the display apparatus may be implemented. The scope of the disclosure is not limited by these effects.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A display apparatus comprising:
a substrate comprising a display area and a non-display area outside the display area;
a pixel disposed in the display area and comprising a pixel circuit and a light-emitting diode electrically connected to the pixel circuit;
a first power voltage line disposed in the non-display area and configured to transmit a first power voltage;
a second power voltage line disposed in the non-display area and configured to transmit a second power voltage; and
a first dummy circuit disposed in the non-display area and configured to operate as a sink-current path electrically connecting the first power voltage line to the second power voltage line.

2. The display apparatus of claim 1, wherein the pixel circuit comprises:
a first transistor comprising a first terminal electrically connected to a first node, a gate electrically connected to a second node, and a second terminal electrically connected to a third node;
a second transistor electrically connected between a data line and the first node;
a third transistor electrically connected between the first power voltage line and the first node;
a fourth transistor electrically connected between the third node and a fourth node; and
a fifth transistor electrically connected between a bias voltage line and the first node, and
wherein the light-emitting diode is electrically connected to the fourth node.

3. The display apparatus of claim 2, wherein the pixel circuit further comprises:
a sixth transistor electrically connected between the second node and the third node;
a seventh transistor electrically connected between a first initialization voltage line and the second node; and
an eighth transistor electrically connected between a second initialization voltage line and the fourth node.

4. The display apparatus of claim 1, wherein the first dummy circuit comprises:
a first transistor comprising a first terminal electrically connected to a first node, a gate electrically connected to a second node, and a second terminal electrically connected to a third node;
a second transistor electrically connected between a data line and the first node;
a third transistor electrically connected between the first power voltage line and the first node;
a fourth transistor electrically connected between the third node and a fourth node;
a fifth transistor electrically connected between a bias voltage line and the first node; and
a sixth transistor electrically connected between the fourth node and an auxiliary electrode or auxiliary voltage line configured to transmit the second power voltage.

5. The display apparatus of claim 4, wherein the first dummy circuit further comprises:
a seventh transistor electrically connected between the second node and the third node;
an eighth transistor electrically connected between a first initialization voltage line and the second node; and
a ninth transistor electrically connected between a second initialization voltage line and the fourth node.

6. The display apparatus of claim 3, wherein a gate of each of the third transistor, the fourth transistor, and the sixth transistor is electrically connected to an emission control line.

7. The display apparatus of claim 3, wherein a frame comprises a first scan period in which a data signal is supplied to the data line and the pixel emits light with a brightness corresponding to the data signal, and a second scan period in which the data signal supplied in the first scan period is maintained and the pixel emits light with the brightness corresponding to the data signal, and
wherein a gate-on voltage is supplied to a gate of the fifth transistor during each of the first scan period and the second scan period.

8. The display apparatus of claim 7, wherein the second scan period comprises a non-emission period and an emission period, and
wherein during the emission period, the third transistor, the fourth transistor, and the sixth transistor operate as the sink-current path.

9. The display apparatus of claim 4, wherein the bias voltage line is configured to transmit a bias voltage to the first node, and
wherein a level of the bias voltage is higher than a level of the first power voltage.

10. The display apparatus of claim 1, further comprising a second dummy circuit disposed in the non-display area,
wherein the light-emitting diode comprises:
a pixel electrode electrically connected to the pixel circuit;
an opposite electrode; and
an emission layer between the pixel electrode and the opposite electrode, and
the second dummy circuit is electrically insulated from the opposite electrode.

11. A display apparatus comprising:
a substrate comprising a display area and a non-display area outside the display area;
a pixel disposed in the display area and comprising a pixel circuit and a light-emitting diode electrically connected to the pixel circuit;
a first power voltage line disposed in the non-display area and configured to transmit a first power voltage;
a first voltage line disposed in the non-display area and configured to transmit a first voltage lower than the first power voltage;
a controller disposed in the non-display area and configured to output a sink-control signal; and
a sink-transistor disposed in the non-display area and configured to operate as a sink-current path electrically connecting the first power voltage line to the first voltage line based on the sink-control signal.

12. The display apparatus of claim 11, wherein the sink-transistor comprises a first terminal electrically connected to the first power voltage line, a second terminal electrically connected to the first voltage line, and a gate electrically connected to the controller.

13. The display apparatus of claim 11, wherein the light-emitting diode comprises:
a pixel electrode electrically connected to the pixel circuit;
an opposite electrode; and
an emission layer between the pixel electrode and the opposite electrode, and
wherein the first voltage line is electrically connected to the opposite electrode.

14. The display apparatus of claim 11, wherein the pixel circuit comprises:
a first transistor comprising a first terminal electrically connected to a first node, a gate electrically connected to a second node, and a second terminal electrically connected to a third node;
a second transistor electrically connected between a data line and the first node;
a third transistor electrically connected between the first power voltage line and the first node;
a fourth transistor electrically connected between the third node and a fourth node; and
a fifth transistor electrically connected between a bias voltage line and the first node, and
wherein the light-emitting diode is electrically connected to the fourth node.

15. The display apparatus of claim 14, wherein the pixel circuit further comprises:
a sixth transistor electrically connected between the second node and the third node;
a seventh transistor electrically connected between a first initialization voltage line and the second node; and
an eighth transistor electrically connected between a second initialization voltage line and the fourth node.

16. The display apparatus of claim 15, wherein the first voltage line is electrically connected to the first initialization voltage line or the second initialization voltage line.

17. The display apparatus of claim 11, wherein the sink-transistor is disposed to be adjacent to the controller.

18. The display apparatus of claim 17, wherein the substrate comprises a first area overlapping the display area, a second area outside the first area, and a bending area between the first area and the second area, and
wherein the sink-transistor is disposed in the second area.

19. An electronic device comprising:
the display apparatus of claim 1;
a memory configured to store an application; and
one or more processors configured to execute the application and transmit an image data signal and an input control signal to the display apparatus.

20. An electronic device comprising:
a display apparatus;
a memory configured to store an application; and
one or more processors configured to execute the application and transmit an image data signal and an input control signal to the display apparatus,
wherein the display apparatus comprises:
a substrate comprising a display area and a non-display area outside the display area;
a pixel disposed in the display area and comprising a pixel circuit and a light-emitting diode electrically connected to the pixel circuit;
a first power voltage line disposed in the non-display area and configured to transmit a first power voltage;
a first voltage line disposed in the non-display area and configured to transmit a first voltage lower than the first power voltage;
a controller disposed in the non-display area and configured to output a sink-control signal; and
a sink-transistor disposed in the non-display area and configured to operate as a sink-current path electrically connecting the first power voltage line to the first voltage line based on the sink-control signal.
